(19) United States
(12) Patent Application Publication
(10) Pub. No.: US 2018/0040643 A1
(43) Pub. Date: Feb. 8, 2018

(54) ARRAY SUBSTRATE AND DISPLAY DEVICE

(71) Applicant: BOE TECHNOLOGY GROUP CO., LTD., Beijing (CN)

(72) Inventors: Yongchun LU, Beijing (CN); Jianbo XIAN, Beijing (CN)

(73) Assignee: BOE TECHNOLOGY GROUP CO., LTD., Beijing (CN)

(21) Appl. No.: 15/528,659

(22) PCT Filed: Sep. 14, 2016
(86) PCT No.: PCT/CN2016/098951

§ 371 Date: May 22, 2017

(30) Foreign Application Priority Data
Dec. 30, 2015 (CN) 201521133749.X

(51) Int. Cl. H01L 27/12; G02F 1/1333; G02F 1/1345; H01L 23/544

(52) U.S. Cl. CPC H01L 27/1248; H01L 27/124; H01L 23/544; G02F 1/133345; G02F 1/13458; H01L 2223/54426; G02F 1/1368

(57) ABSTRACT

An array substrate includes a display region (12), a bonding region (13), and a planarization layer (14), and a thickness of at least a portion of the pattern of the planarization layer (14) provided in the display region (12) is larger than a thickness of the pattern of the planarization layer (14) provided in the bonding region (13). In the array substrate, the upper surface of the display region is higher than the upper surface of the bonding region of the array substrate, thus, it is possible to reduce or avoid the phenomenon of bad bonding in the bonding region. A display device is further provided.

### TECHNICAL FIELD

Embodiments of the present disclosure relate to an array substrate and a display device.

### BACKGROUND

A thin film transistor liquid crystal display panel (TFT-LCD) at least comprises an array substrate, generally, the array substrate is provided with a plurality of wiring layers, such as the layers for gate lines, source electrodes and drain electrodes, and so on. The introduction of the wiring layers may lead to an uneven surface of the array substrate. In general, an organic resin layer is disposed on the entire surface of the array substrate, and the organic resin layer may ensure that the flatness of a display region and the optical effect of a device are not affected as much as possible.

However, in the process of manufacturing an array substrate, a planarization layer is generally formed in one process and distributed on the entire surface of the array substrate. The thickness of the planarization layer in a bonding region is substantially the same as the thickness of the planarization layer in the display region. However, because the bonding region is provided with a plurality of connecting structures, such as via hole connections, a step difference is formed between the bottom surface of the connecting structures and the top surface of the circuits in the bonding region, and the existence of the step difference is easy to cause the phenomenon of bad bonding in the bonding region.

### SUMMARY

Embodiments of the present disclosure provide an array substrate and a display device. On the array substrate, an upper surface of a planarization layer provided in a display region is higher than an upper surface of a planarization layer provided in a bonding region, thus, it is possible to reduce or avoid the phenomenon of bad bonding in the bonding region.

At least one embodiment of the present disclosure provides an array substrate, and the array substrate comprises a display region and a bonding region, and the array substrate further comprises a planarization layer, a thickness of at least a portion of the pattern of the planarization layer provided in the display region is larger than a thickness of the pattern of the planarization layer provided in the bonding region.

For example, the array substrate provided in at least one embodiment of the present disclosure further comprises a transition region which is provided between the display region and the bonding region, and a thickness of at least a portion of the pattern of the planarization layer provided in the transition region is less than or equal to the thickness of the pattern of the planarization layer provided in the display region.

For example, in the array substrate provided in at least one embodiment of the present disclosure, the thickness of the at least a portion of the pattern of the planarization layer provided in the transition region is larger than the thickness of the pattern of the planarization layer provided in the bonding region.

For example, in the array substrate provided in at least one embodiment of the present disclosure, the thickness of the at least a portion of the pattern of the planarization layer provided in the transition region is equal to the thickness of the pattern of the planarization layer provided in the bonding region.

For example, the array substrate provided in at least one embodiment of the present disclosure further comprises a transition region which is provided between the display region and the bonding region, and a thickness of the at least a portion of the pattern of the planarization layer provided in the transition region is larger than or equal to the thickness of the pattern of the planarization layer provided in the bonding region.

For example, in the array substrate provided in at least one embodiment of the present disclosure, the thickness of the at least a portion of the pattern of the planarization layer provided in the bonding region is ⅕ to 1/20 of the thickness of the pattern of the planarization layer provided in the display region; and the thickness of the pattern of the planarization layer provided in the bonding region is ¼ to 1/10 of the thickness of the at least a portion of the pattern of the planarization layer provided in the transition region.

For example, in the array substrate provided in at least one embodiment of the present disclosure, the thickness of the pattern of the planarization layer provided in the bonding region is zero.

For example, in the array substrate provided in at least one embodiment of the present disclosure, at least a portion of the pattern of the planarization layer provided in the transition region is a discontinuous structure or a continuous structure.

For example, the array substrate provided in at least one embodiment of the present disclosure further comprises gate lines and data lines, along at least one of the gate lines, the pattern of the planarization layer provided in the transition region is a discontinuous structure; along at least one of the data lines, the pattern of the planarization layer provided in the transition region is a continuous structure.

For example, in the array substrate provided in at least one embodiment of the present disclosure, the pattern of the planarization layer provided in the transition region is close to at least a portion of the gate lines or the data lines of the display region, or the pattern of the planarization layer provided in the transition region is provided around the gate lines or the data lines of the display region.

For example, in the array substrate provided in at least one embodiment of the present disclosure, the pattern of the planarization layer provided in the transition region is provided at junctions of the gate lines and leading wires of the gate lines; or the pattern of the planarization layer provided in the transition region is provided at junctions of the data lines and leading wires of the data lines.

For example, the array substrate provided in at least one embodiment of the present disclosure further comprises thin film transistors and pixel electrodes, the data lines and the pixel electrodes are electrically connected with the thin film transistors, the planarization layer is provided between the layer where the pixel electrodes are provided and the layer where the data lines are provided.

For example, the array substrate provided in at least one embodiment of the present disclosure further comprises common electrodes, the planarization layer is provided between the common electrodes and the pixel electrodes, the thickness of the at least a portion of the pattern of the planarization layer provided in the display region is larger than the thickness of the pattern of the planarization layer provided in the bonding region.

For example, in the array substrate provided in at least one embodiment of the present disclosure, the common electrodes and the gate lines are provided in a same layer.

For example, in the array substrate provided in at least one embodiment of the present disclosure, at least a portion of the pattern of the planarization layer provided in the transition region is an alignment mark or an antistatic protective layer.

For example, in the array substrate provided in at least one embodiment of the present disclosure, the shape of the at least a portion of the pattern of the planarization layer provided in the transition region is a square, a rectangular or a circular.

For example, in the array substrate provided in at least one embodiment of the present disclosure, at least a portion of the patterns of the planarization layer provided in the transition region are arranged in a matrix or are staggered in arrangement.

For example, in the array substrate provided in at least one embodiment of the present disclosure, the array substrate further comprises supports on the patterns of the planarization layer in the transition region.

For example, in the array substrate provided in at least one embodiment of the present disclosure, the planarization layer is a resin layer or a color film layer.

At least one embodiment of the present disclosure further provides a display device, and the display device comprises the above-mentioned array substrate.

### BRIEF DESCRIPTION OF THE DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a cross section structure schematic view of an array substrate provided by an embodiment of the present disclosure;

FIG. 2 is a top view structure schematic view of an array substrate provided by an embodiment of the present disclosure;

FIG. 3 is a top view structure schematic view of a second array substrate provided by an embodiment of the present disclosure;

FIG. 4 is a cross section structure schematic view of the second array substrate provided by an embodiment of the present disclosure;

FIG. 5 is a cross section structure schematic view of a third array substrate provided by an embodiment of the present disclosure;

FIG. 6 is a cross section structure schematic view of a fourth array substrate provided by an embodiment of the present disclosure;

FIG. 7 is a top view structure schematic view of the third array substrate provided by an embodiment of the present disclosure;

FIG. 8 is a top view structure schematic view of a fifth array substrate provided by an embodiment of the present disclosure;

FIG. 9 is a top view structure schematic view of a sixth array substrate provided by an embodiment of the present disclosure;

FIG. 10 is a top view structure schematic view of a seventh array substrate provided by an embodiment of the present disclosure;

FIG. 11 is a top view structure schematic view of an eighth array substrate provided by an embodiment of the present disclosure;

FIG. 12 is a top view structure schematic view of a ninth array substrate provided by an embodiment of the present disclosure;

FIG. 13 is a top view structure schematic view of a tenth array substrate provided by an embodiment of the present disclosure;

FIG. 14 is a cross section structure schematic view of the fourth array substrate provided by an embodiment of the present disclosure;

FIG. 15 is a cross section structure schematic view of the fifth array substrate provided by an embodiment of the present disclosure; and

FIG. 16 is a top view structure schematic view of an eleventh array substrate provided by an embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art may obtain other embodiment(s), without any inventive work, which should be within the scope of the disclosure.

It should be noted that, in the embodiments and the drawings of the present disclosure, in a case of describing an element A disposed “above” or “below” of another element B, it may indicate that the element A is disposed directly “above” or “below” the element B, or that there are other media elements between A and B. Element A or element B may be a layer, a region, or a substrate etc., other media elements may also be layers, regions, or substrates etc., which are not limited here. On the contrary, in a case of describing A disposed “directly” “above” or “below” B, it indicates that there is no other media elements between A and B. In a case of describing a component C “connected” or “electrically connected” with a component D, it indicates that the component C is directly or indirectly connected or electrically connected with the component D. The component C or component D may be a thin film transistor, a diode, a capacitor, a resistor, a gate line, a data line, a common electrode, a leading wire, a bonding wire and other kinds of connecting wires, which are not limited here.

Embodiments of the present disclosure provide an array substrate and a display device, the array substrate comprises a display region and a bonding region, and the array substrate further comprises a planarization layer, a thickness of at least a portion of the pattern of the planarization layer provided in the display region is larger than a thickness of the pattern of the planarization layer provided in the bonding region, so that the upper surface of the planarization layer provided in the display region is higher than the upper surface of the planarization layer provided in the bonding region, thus, it is possible to reduce or avoid the phenomenon of bad bonding in the bonding region.

The array substrate may be divided into a plurality of regions which comprises a display region and a bonding region, these regions may be adjacent to each other or not adjacent to each other, or some regions may partially overlap with each other.

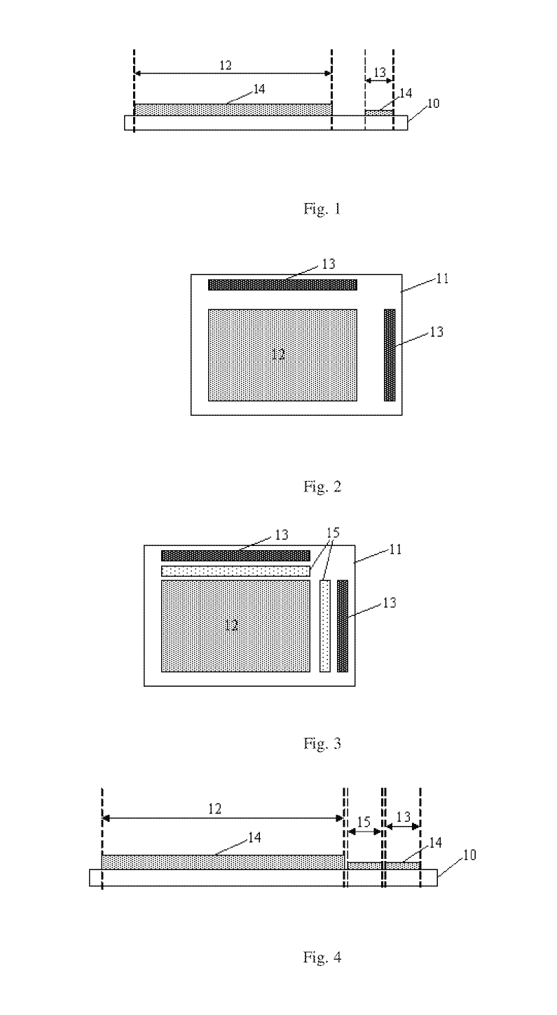

For example, FIG. 1 is a cross section structure schematic view of an array substrate provided by an embodiment of the present disclosure, and the array substrate comprises a display region 12 and a bonding region 13, and the array substrate further comprises a planarization layer 14, a thickness of at least a portion of the pattern of the planarization layer 14 provided in the display region 12 is larger than a thickness of the pattern of the planarization layer 14 provided in the bonding region. For example, as illustrated in FIG. 1, the array substrate further comprises a base substrate 10. It should be noted that, other layers may also be disposed between the base substrate 10 and the planarization layer 14, for example, one or more layers selected from a gate line layer, a gate insulating layer, an active layer, a source-drain electrode layer and a passivation layer, these films may be manufactured through patterning processes, and detailed descriptions will be omitted in the present disclosure.

For example, FIG. 2 is a top view structure schematic view of an array substrate provided by an embodiment of the present disclosure, as illustrated in FIG. 2, the array substrate 11 comprises a display region 12 and a bonding region 13, both the display region 12 and the bonding region 13 are provided with a planarization layer, and the thickness of at least a portion of the pattern of the planarization layer provided in the display region 12 is larger than the thickness of the pattern of the planarization layer provided in the bonding region 13.

For example, the distribution scope of the bonding region is not limited to one or more of a left side, a right side, an upper side and a lower side of the display region, the distribution scope of the bonding region may be the whole region or a local region provided on one side or more sides of the display region, which are not limited in the present disclosure.

For example, in a case that the planarization layer is provided in the display region, the planarization layer plays a role of flattening the display region; in a case that the planarization layer is provided in the bonding region, the thickness of the pattern of the planarization layer provided in the bonding region is less than the thickness of the pattern of the planarization layer provided in the display region, which enables the step difference, between the bottom surface of the bonding region and the upper surface of the bonding region, of the connection structure which passes through the planarization layer to reduce, so that the phenomenon of bad bonding in the bonding region is reduced or avoided.

Exemplary, the planarization layer is disposed in the entire display region or the entire bonding region, or the planarization layer is disposed in a portion of the display region or a portion of the bonding region. The thickness of the pattern of the planarization layer provided in the bonding region is zero or close to zero, or larger than zero. That is, the planarization layer is distributed in the bonding region, or not distributed in the bonding region. The thickness of the pattern of the planarization layer provided in the bonding region is less than the thickness of the at least a portion of the pattern of the planarization layer provided in the display region, in this way, the upper surface of the planarization layer provided in the display region is higher than the upper surface of the planarization layer provided in the bonding region, thus, in the case of bonding, it is possible to reduce or avoid the phenomenon of bad bonding.

For example, FIG. 3 is a top view structure schematic view of a second array substrate provided by an embodiment of the present disclosure. As illustrated in FIG. 3, the array substrate is provided with a transition region 15 which is provided between the display region 12 and the bonding region 13, and FIG. 4 is a cross section structure schematic view of the array substrate illustrated in FIG. 3. As illustrated in FIG. 4, a thickness of at least a portion of the pattern of the planarization layer 14 provided in the transition region 15 is less than or equal to the thickness of the pattern of the planarization layer 14 provided in the display region 12.

It should be noted here that, the thicknesses of the planarization layers in the display region, the bonding region and the transition region are the thicknesses of the planarization layers by themselves in each of the regions.

For example, the transition region is a region between the display region and the bonding region. In general, the transition region comprises wiring layers of the leading wires for the gate lines or the data lines that are in the display region and via holes disposed between the wiring layers. The wiring layers render the transition region uneven, so that the planarization layer distributed in the transition region plays the role of flattening the transition region, the transition region is provided between the display region and the bonding region, a planarization layer with a certain thickness disposed in the transition region plays a role of transition of the pattern thickness difference between the display region and the bonding region.

For example, the planarization layer is distributed in the whole transition region, or distributed in a portion of the transition region, that is, the thickness of a portion of the pattern of the planarization layer provided in the transition region is zero or close to zero.

For example, a thickness of the at least a portion of the pattern of the planarization layer provided in the transition region is less than or equal to the thickness of the pattern of the planarization layer provided in the display region.

For example, the thickness of the at least a portion of the pattern of the planarization layer provided in the transition region is larger than the thickness of the pattern of the planarization layer provided in the bonding region, or the thickness of the at least a portion of the pattern of the planarization layer provided in the transition region is less than or equal to a thickness of the pattern of the planarization layer provided in the bonding region.

For example, the thickness of the pattern of the planarization layer provided in the transition region is less than or equal to the thickness of the pattern of the planarization layer provided in the display region, and the thickness of the pattern of the planarization layer provided in the transition region is larger than a thickness of the pattern of the planarization layer provided in the bonding region.

For example, the thickness of the pattern of the planarization layer provided in the transition region is less than or equal to a thickness of the pattern of the planarization layer provided in the display region, and the thickness of the at least a portion of the pattern of the planarization layer provided in the transition region is larger than the thickness of the pattern of the planarization layer provided in the bonding region, or the thickness of the at least a portion of the pattern of the planarization layer provided in the transition region is equal to the thickness of the pattern of the planarization layer provided in the bonding region.

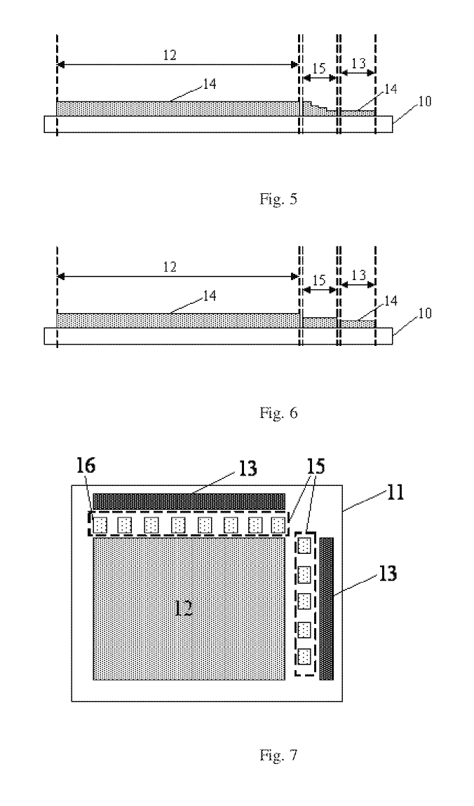

For example, FIG. 5 is a cross section structure schematic view of a third array substrate provided by an embodiment of the present disclosure, as illustrated in FIG. 5, from the display region to the bonding region, the thickness of the pattern of the planarization layer 14 provided in the transition region 15 varies in a form of continuously decreasing or in a form of stepwise decreasing.

FIG. 6 is a cross section structure schematic view of a fourth array substrate provided by an embodiment of the present disclosure, as illustrated in FIG. 6, the thickness of the pattern of the planarization layer 14 provided in the transition region 15 is larger than the thickness of the pattern of the planarization layer 14 provided in the bonding region 13.

It should be noted that, the difference of the thicknesses among the planarization layer in the display region, the bonding region and the transition region may be set according to the actual situations.

For example, the thickness of the pattern of the planarization layer provided in the bonding region is ⅕ to 1/20 of the thickness of the pattern of the planarization layer provided in the display region. For example, the thickness of the pattern of the planarization layer provided in the bonding region is 0.25 microns, and the thickness of the pattern of the planarization layer provided in the display region is 2.5 microns.

For example, the thickness of the pattern of the planarization layer provided in the bonding region is ¼ to 1/10 of the thickness of the pattern of the planarization layer provided in the transition region. For example, the thickness of the pattern of the planarization layer provided in the bonding region is 0.25 microns, and the thickness of the pattern of the planarization layer provided in the transition region is 1 microns.

For example, the thickness of the pattern of the planarization layer provided in the bonding region is zero, that is, the planarization layer is not formed in the bonding region, and the thickness of the pattern of the planarization layer provided in the transition region is equal to or nearly equal to the thickness of the pattern of the planarization layer provided in the display region.

It should be noted that, in the present embodiment, the adjustment of the thicknesses of the patterns of the planarization layers provided in the display region, the bonding region and/or the transition region may be accomplished in a production process, and for example, the production process comprises patterning, printing or other production process. For example, in the present embodiment, the adjustment of the thicknesses of the patterns of the planarization layers provided in the display region, the bonding region and/or the transition region may be accomplished in a same production process or in different production processes, and for example, accomplished in an etching step of a same patterning process. Of course, the planarization layer with different thicknesses in a same region may also be accomplished in a same production process or in different production processes. For example, the planarization layer in the display region may be manufactured in a production process or in production processes, and therefore, the thickness or thicknesses of the planarization layer provided in the display region are not absolutely equal.

For example, the position, quantity and shape of the patterns of the planarization layers in the transition region are not limited here.

For example, the pattern of the planarization layer in the transition region may be provided along the gate lines and/or the data lines. Further, the planarization layer is close to at least a portion of the gate lines and/or the data lines in the display region, or the planarization layer is provided around the gate lines or the data lines. Of course, the shape and the quantity of the patterns of the planarization layers provided along the gate lines and/or the data lines may be the same or different.

For example, the pattern of the planarization layer provided in the transition region is a discontinuous structure. For example, the planarization layers are distributed at an interval, which is illustrated in FIG. 7 to FIG. 9.

For example, the pattern of the planarization layer provided in the transition region is a continuous structure. For example, the planarization layer is a plate-like, which is illustrated in FIG. 10.

For example, the patterns of the planarization layer provided in the transition region may be arranged in an orderly arrangement structure, for example, a plurality of patterns of the planarization layer are arranged in a matrix structure, or a plurality of patterns of the planarization layer are continuous arranged in a row, or patterns of the planarization layer are staggered in arrangement with respect to each other, which are not limited in the present embodiment.

Exemplary, the pattern of the planarization layer provided in the transition region is an alignment mark.

In the present embodiment, in order to ensure the accuracy of the assembly of the array substrate and the alignment substrate (for example, a color film substrate), the array substrate is generally provided with an alignment mark. In the present embodiment, the pattern of the planarization layer in the transition region is configured as the alignment mark. That is in the case that the alignment mark is configured as a sign, the alignment accuracy of the array substrate and the substrate is improved.

For example, the shape of the at least a portion of the pattern of the planarization layer provided in the transition region is a square, a rectangular or a circular.

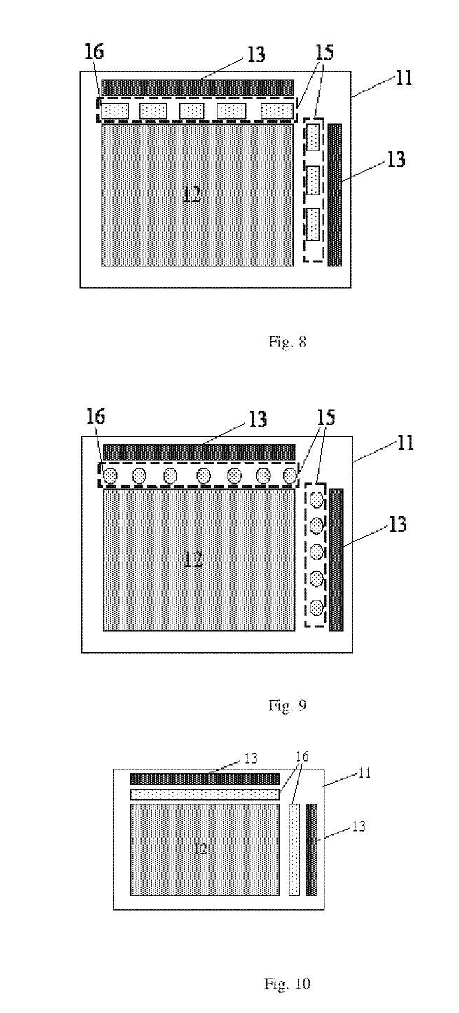

For example, the pattern of the planarization layer in the transition region is configured as the alignment mark, and the number of the patterns of the alignment mark may be one or more, the patterns of the alignment mark are in various shapes. Referring to FIG. 7, the pattern of the alignment mark 16 is a square; referring to FIG. 8, the pattern of the alignment mark 16 is a rectangular; referring to FIG. 9, the pattern of the alignment mark 16 is a circular, or referring to FIG. 10, the pattern of the alignment mark 16 is distributed in the whole transition region.

It should be noted that, the pattern of the alignment mark may be any other kind of shape, which is not limited in the present embodiment.

For example, the number of the patterns of the alignment mark is plural.

Exemplary, the number of the patterns of the alignment mark may be one or more, in a case that the number of the patterns of the alignment mark in the transition region is plural, the patterns of the alignment mark in the array substrate are the same, or are different, which are not limited here.

For example, the patterns of the alignment mark are close to at least a portion of the gate lines and/or the data lines of the display region, or the patterns of the alignment mark are provided around the gate lines or the data lines of the display region.

For example, the transition region comprises the leading wires of the gate lines or the data lines of the display region, and the via holes which are configured for connecting the wires, the patterns of the alignment mark are provided around the gate lines or the data lines in the display region. For example, in the transition region for the gate lines, the patterns of the alignment mark are provided at the junctions of the gate lines in the display region and the leading wires of the gate lines; or in the transition region for the data lines, the patterns of the alignment mark are provided at the junctions of the data lines in the display region and the leading wires of the data lines.

For example, the patterns of the alignment mark are pads which are provided at the junctions of the gate lines in the display region and the leading wires of the gate lines (the pads are the leading pads of the gate lines in the display region, which is convenient for the stable connection of the gate lines in the display region with the connecting wires for the gate line), in this way, it is possible to make full use of the space of the array substrate without arranging additional alignment marks.

For example, a plurality of patterns of the alignment marks are arranged in a matrix.

Exemplary, in the case that the number of the patterns of the alignment marks is plural, the patterns of the alignment mark may be arranged into an ordered arrangement structure, for example, the patterns of the alignment marks are arranged in a matrix, or the patterns of the alignment marks are continuously arranged in a line, or the patterns of the alignment marks are arranged in a stagger way, which are not limited here.

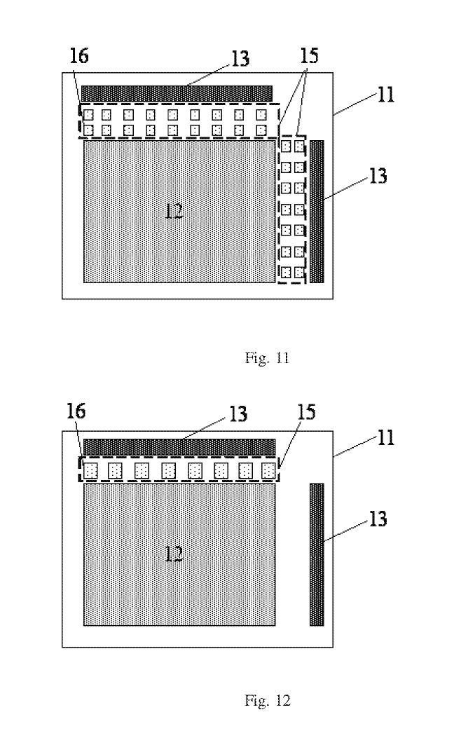

Exemplary, referring to FIG. 11, in the case that the number of the patterns of the alignment marks 16 is plural, the patterns of the alignment marks 16 are arranged in a matrix, or referring to FIG. 12, the patterns of the alignment marks 16 are arranged in a line or in a column.

Exemplary, the pattern of the planarization layer provided in the transition region is an antistatic protective layer which is configured for preventing the electrostatic breakdown in the transition region.

Exemplary, in the transition region, for example, the planarization layer arranged at the positions where the gate line layer is connected with the data line layer through via holes is configured as the antistatic protective layer, and the antistatic protective layer is configured for preventing the via hole structure from being electrostatic breakdown by the accumulation of electrostatic charges in the technology process. It should be noted that, the gate line layer and the data line layer may be directly connected through via holes, or connected at the positions where the via holes are provided by means of another conductive layer (such as a pixel electrode of ITO material). That is the antistatic protective layer is provided above the hole position, or the via holes pass through the antistatic protective layer.

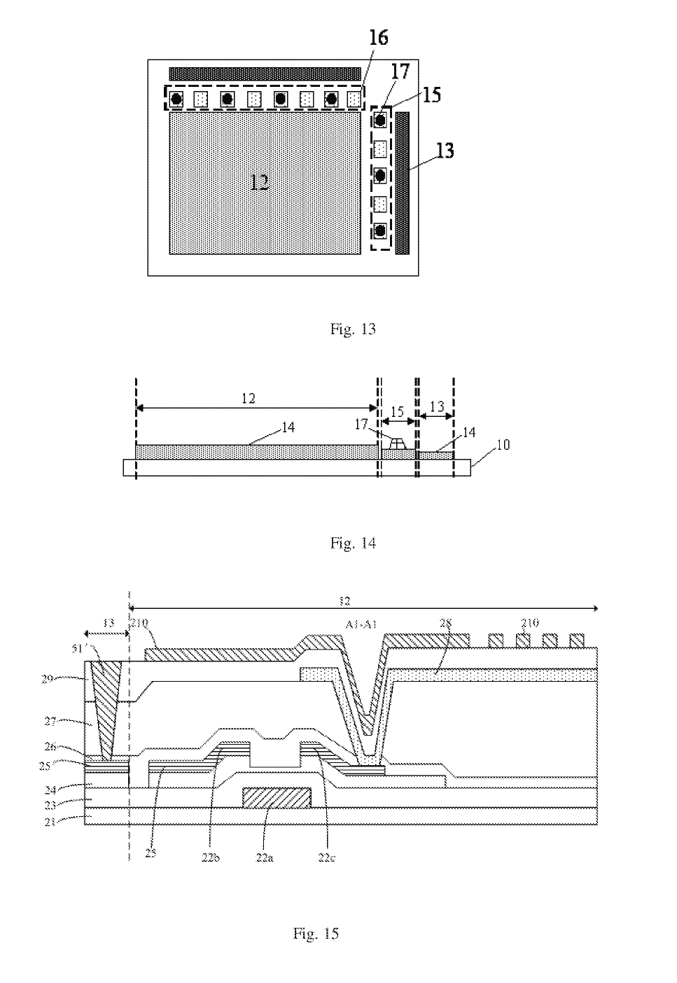

For example, FIG. 13 is a top view structure schematic view of a tenth array substrate provided by an embodiment of the present disclosure. Referring to FIG. 13, the array substrate further comprises supports 17 on the patterns of the alignment marks 16 in the transition region 15. The projection of the support 17 in the transition region is a circular, and the shape of the support is only drawn by taking circle as an example. In the present disclosure, the projection of the support is not limited to be circular.

For example, FIG. 14 is a cross section structure schematic view of the fourth array substrate provided by an embodiment of the present disclosure. Referring to FIG. 14, the supports 17 are provided on the patterns of planarization layer in the transition region, and the shape of the support is not limited here.

For example, as illustrated in FIG. 14, support structures or spacers (PS) are arranged on the structure provided with the patterns of the alignment marks in the transitional region, and the support structures are main supports or auxiliary supports. In the case that the number of the patterns of the alignment marks in the transition region is plural, the supports may be disposed on each of the patterns of the alignment marks, or disposed on a portion of the patterns of the alignment marks. Therefore, in the case that the alignment accuracy of the array substrate and the color film substrate is achieved by the patterns of the alignment marks, the supports arranged on the patterns of the alignment marks can not only support the cell gap of the cell, but also can avoid the bad display caused by the bending of the array substrate during the process of preparation or transportation.

It should be noted that, the supports on the patterns of the alignment marks of the planarization layer on the array substrate may be manufactured with other film of the array substrate, and for example, manufactured with a conductive layer (for example, a source drain electrode layer, a pixel electrode layer) or a non-conductive layer (for example, an insulating layer) of the array substrate, and detailed descriptions will be omitted here.

For example, the number of the supports is plural.

Exemplary, the array substrate is provided with one or more supports. In the case that the patterns of the planarization layer in the transition region cover the whole transition region, the supports may be provided separately in the pattern of the planarization layer or distributed at two ends of the transition region, which is not limited in the present disclosure.

For example, the planarization layer is a resin layer or a color film layer.

Exemplary, the planarization layer is a resin layer or a color film layer. In the case that the planarization layer is made of a resin and this resin layer may be provided in the display region, the power consumption of the device can be reduced by the lower dielectric constant of the resin layer. For example, the resin dielectric layer disposed between the pixel electrode and the data line can reduce the power consumption of the device. Of course, if the resin layer is provided in the bonding region, the resin layer may be configured as a protective layer for preventing the bonding region from being electrostatic breakdown; if the resin layer is provided in the transition region, the resin layer may be configured as an alignment mark or a protective layer for preventing the transition region from being electrostatic breakdown.

In the case that the color film layer is arranged on the array substrate (Color Filter on Array, COA), that is, the planarization layer is one or more patterns of the color film layer. In general, the color film layer comprises three kinds of patterns, R, G and B, of course, the color film layer further comprises a pattern in other color(s). In the case that the color film is provided in the display region, the color film is configured for transmissive display. In the case that the color film is provided in the bonding region, the color film is configured as a protective layer for preventing the bonding region from being electrostatic breakdown. In the case that the color film is provided in the transition region, the color film is configured as an alignment mark or an antistatic protective layer for preventing the transition region from being electrostatic breakdown.

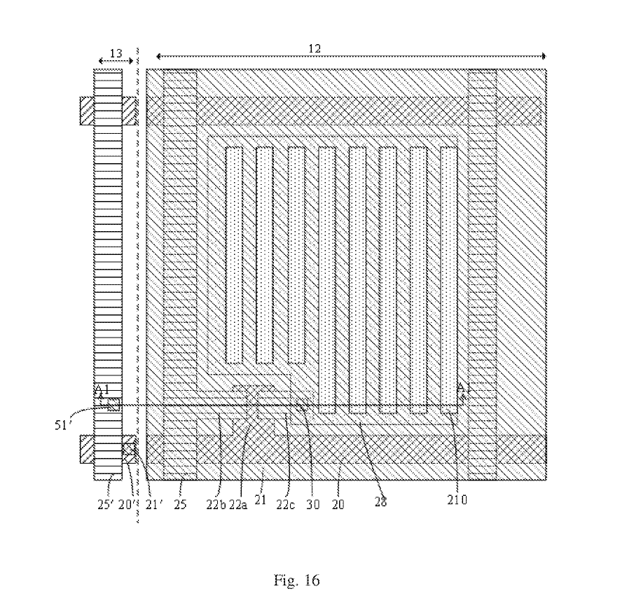

The following takes the planarization layer as a color film layer for example, referring to FIG. 15 and FIG. 16, the array substrate comprises: a display region 12, a gate line 20 and a gate electrode 22a of a thin film transistor, a gate insulating layer 23, an active layer 24 of the thin film transistor, a source electrode 22b and a drain electrode 22c of the thin film transistor, a data line 25, a passivation layer 26, a color film layer 27, a pixel electrode layer 28, a second insulating layer 29, and a common electrode 210 which are formed on the substrate 21 sequentially.

For example, the gate line 20 and the gate electrode 22a of the thin film transistor are arranged in a same layer and electrically connected with each other, the source electrode 22b of the film transistor is electrically connected with the data line 25, the drain electrode 22c of the thin film transistor is electrically connected with the pixel electrode layer 28 through the via hole 30.

For example, the bonding region 13 of the array substrate comprises a bonding data line 25′, the upper surface of the color film above the bonding data line 25 is lower than the upper surface of the color film layer in the display region, thus, it is possible to reduce or avoid the phenomenon of bad bonding in the bonding region.

Referring to FIG. 15 and FIG. 16, the bonding region 13 of the array substrate is provided with a bonding gate line 20′ and a bonding data line 25′ which are configured for bonding to drive circuits, the bonding gate line 20′ and the gate line 20 are arranged in a same layer, and the bonding data line 25′ and the data line 25 are arranged in a same layer; the bonding gate line 20′ is connected with the gate line 20 through a via hole 21′; a data line connecting hole 51′ is disposed on the bonding data line 25′, and the data line connecting hole 51′ passes through the second insulating layer 29, the color film layer 27 and the passivation layer 26. In addition, in the process that the common electrode 210 is formed, a common electrode metal is filled in the gate line connecting hole and the data line connecting hole 51′, so as to play a role of improving the conduction effect of the bonding to the driving circuits.

For example, the second insulating layer 29 disposed between the layer where the common electrode is provided and the layer where the data lines are provided is a resin layer, and the thickness of the pattern of the resin layer in the display region is larger than the thickness of the pattern of the resin layer on the color film layer provided in the bonding region, that is, the upper surface of the resin layer provided in the bonding region is lower than the upper surface of the resin layer provided in the display region, thus, it is capable of further reducing or avoiding the phenomenon of bad bonding in the bonding region.

It should be noted that, the structure of the array substrate described above is only illustrated for example, and the design of the color film layer is not limited to the design of the color film layer in the structure of the array substrate provided by the present embodiment.

Of course, the design of the color film layer may also be applied to other structures of array substrates, for example.

First manner: referring to FIG. 15, the array substrate may neither include a common electrode 210 nor a second insulating layer 29. The material filled in the data line connecting hole 51′ may be a separate conductive material or the material of the pixel electrode.

Second manner: referring to FIG. 15, a material of the common electrode 210 is the same as a material of the gate line, the common electrode 210 and the gate line are manufactured in a same production process. The material filled in the data line connecting hole 51′ may be a separate conductive material or the material of the pixel electrode. Of course, it may not include the second insulating layer 29 and/or the passivation layer 26.

A display device provided by an embodiment of the present disclosure comprises any one of the above-mentioned array substrates.

The display device provided by an embodiment of the present disclosure comprises any one of the above-mentioned array substrates, and therefore, the display device provided by the present embodiment is capable of avoiding the phenomenon of bad bonding in the bonding region.

It should be noted that, the display device provided by at least one embodiment of the present disclosure is an electronic device such as a liquid crystal display panel, a liquid crystal display, an organic light emitting device, an electronic paper or a camera, etc.

An array substrate and a display device are provided by at least one embodiment of the present disclosure, and the array substrate comprises a display region and a bonding region, and the array substrate is provided with a planarization layer, a thickness of at least a portion of the pattern of the planarization layer provided in the bonding region is less than a thickness of the pattern of the planarization layer provided in the display region, that is, the upper surface of the display region is higher than the upper surface of the bonding region of the array substrate, thus, it is possible to reduce or avoid the phenomenon of bad bonding in the bonding region. Further, the array substrate further comprises a transition region, the thickness of at least a portion of the pattern of the planarization layer provided in the display region is larger than or equal to a thickness of the pattern of the planarization layer provided in the transition region, and the thickness of the at least a portion of the pattern of the planarization layer provided in the transition region is larger than the thickness of the pattern of the planarization layer provided in the bonding region, in this way, the phenomenon of bad bonding in the bonding region can be further reduced and avoided. In addition, the pattern of the planarization layer provided in the transition region may be configured as an alignment mark or an antistatic protective layer, which further improves the alignment accuracy of the array substrate and the substrate, or plays the role of preventing the bonding region from being electrostatic breakdown.

It should be understood, the above embodiments are merely exemplary embodiments for describing the principle of the present disclosure and not limitative to the scope of the present disclosure. Those skilled in the art may make various modifications and variations to the present disclosure but not departing from the spirit and scope of the present disclosure, and these modifications and variations of the present disclosure also belong to the scope of the claims of the present disclosure.

The present application claims the priority of the Chinese Patent Application No. 201521133749.X filed on Dec. 30, 2015, the entirety of which is incorporated herein by reference as a part of the present application.

1. An array substrate, comprising: a display region and a bonding region, wherein the array substrate further comprises a planarization layer, and a thickness of at least a portion of a pattern of the planarization layer provided in the display region is larger than a thickness of a pattern of the planarization layer provided in the bonding region.

2. The array substrate according to claim 1, further comprising a transition region provided between the display region and the bonding region,
wherein a thickness of at least a portion of a pattern of the planarization layer provided in the transition region is a first thickness, and the first thickness is less than or equal to the thickness of the pattern of the planarization layer provided in the display region.

3. The array substrate according to claim 2, wherein the first thickness is larger than the thickness of the pattern of the planarization layer provided in the bonding region.

4. The array substrate according to claim 2, wherein the first thickness is equal to the thickness of the pattern of the planarization layer provided in the bonding region.

5. The array substrate according to claim 1, further comprising a transition region provided between the display region and the bonding region,
wherein a thickness of the at least a portion of a pattern of the planarization layer provided in the transition region is a first thickness, the first thickness is larger than or equal to the thickness of the pattern of the planarization layer provided in the bonding region.

6. The array substrate according to claim 5, wherein a ratio of the thickness of the at least a portion of the pattern of the planarization layer provided in the bonding region to the thickness of the pattern of the planarization layer provided in the display region is ⅕ to 1/20;
a ratio of the thickness of the pattern of the planarization layer provided in the bonding region to the thickness of the at least a portion of the pattern of the planarization layer provided in the transition region is ¼ to 1/10.

7. The array substrate according to claim 2, wherein the thickness of the pattern of the planarization layer provided in the bonding region is zero.

8. The array substrate according to claim 2, wherein at least a portion of the pattern of the planarization layer provided in the transition region is in a discontinuous structure or a continuous structure.

9. The array substrate according to claim 8, further comprising gate lines and data lines,
wherein along at least one of the gate lines, the pattern of the planarization layer provided in the transition region is in a discontinuous structure; and
along at least one of the data lines, the pattern of the planarization layer provided in the transition region is a continuous structure.

10. The array substrate according to claim 9, wherein the pattern of the planarization layer provided in the transition region is close to at least a portion of the gate lines or the data lines of the display region, or
the pattern of the planarization layer provided in the transition region is provided around the gate lines or the data lines of the display region.

11. The array substrate according to claim 9, wherein the pattern of the planarization layer provided in the transition region is provided at junctions of the gate lines and leading wires of the gate lines; or
the pattern of the planarization layer provided in the transition region is provided at junctions of the data lines and leading wires of the data lines.

12. The array substrate according to claim 9, further comprising thin film transistors and pixel electrodes,
wherein the data lines and the pixel electrodes are electrically connected with the thin film transistors, the planarization layer is provided between the layer where the pixel electrodes are provided and the layer where the data lines are provided.

13. The array substrate according to claim 12, further comprising common electrodes,
wherein the planarization layer is provided between the common electrodes and the pixel electrodes, the thickness of the at least a portion of the pattern of the planarization layer provided in the display region is larger than the thickness of the pattern of the planarization layer provided in the bonding region.

14. The array substrate according to claim 13, wherein the common electrodes and the gate lines are provided in a same layer.

15. The array substrate according to claim 2, wherein at least a portion of the pattern of the planarization layer provided in the transition region is an alignment mark or an antistatic protective layer.

16. The array substrate according to claim 15, wherein a shape of the at least a portion of the pattern of the planarization layer provided in the transition region is a square, a rectangular or a circular.

17. The array substrate according to claim 2, wherein at least a portion of the patterns of the planarization layer provided in the transition region are arranged in a matrix or are staggered in arrangement.

18. The array substrate according to claim 2, wherein the array substrate further comprises supports on the patterns of the planarization layer in the transition region.

19. The array substrate according to claim 1, wherein the planarization layer is a resin layer or a color film layer.

20. A display device, comprising the array substrate according to claim 1.
